(19) United States
(12) Patent Application Publication
(10) Pub. No.: US 2016/0005675 A1
(43) Pub. Date: Jan. 7, 2016

(54) Double sided cooling chip package and method of manufacturing the same

(71) Applicant: Infineon Technologies AG, Neubiberg (DE)

(72) Inventor: Chong Yee TONG, Semabok Perdana (MY)

(21) Appl. No.: 14/324,537

(22) Filed: Jul. 7, 2014

(51) Int. Cl. H01L 23/367; H01L 25/065; H01L 25/00; H01L 23/495

(52) U.S. Cl. CPC H01L 23/3672; H01L 23/49575; H01L 25/0657; H01L 25/50

(57) ABSTRACT

A double sided cooling chip package is provided, wherein the package comprises a first heat sink; a second heat sink; a stacked chip arrangement comprising a first electronic chip, a second electronic chip and an interfacing substrate arranged between the first electronic chip and the second electronic chip and comprising electric circuitry on at least one main surface, wherein one of the first electronic chip and the second electronic chip is electrically connected to the electric circuitry of the interfacing substrate; and wherein the first electronic chip is attached to the first heat sink and the second electronic chip is attached to the second heat sink.

### TECHNICAL FIELD

Various embodiments relate to a double sided cooling chip package and a method of manufacturing a double sided cooling chip package.

### BACKGROUND

In the prior art, e.g. EP 2 533 284, power modules having power devices are known, which can be used in high voltage and high current applications. For example, the power module may be a motor drive inverter module with the power devices being power switches. In order for the power devices to perform properly, their temperature must be held within a suitable temperature range. However, the power devices typically generate significant heat, which can cause their temperature to rise outside of the suitable temperature range if the heat is not sufficiently dissipated from the power devices. Thus, the power module, and any packaging which may include the power module, should be constructed so as to effectively cool the power devices.

One approach to cool the power devices may involve utilizing a heat sink thermally coupled to the power devices to assist in dissipating the heat from the power devices. As an example, each of the power devices can be incorporated as one or more dies in the power module. The power module conventionally includes bond wires connecting the dies to conductive traces on a substrate of the power module. The heat sink can be attached to the substrate and can be thermally coupled to the power devices through the substrate.

Furthermore, packages or power modules are known having heat sinks on both major or main surfaces of the power module or package in order to increase the heat dissipation even further.

### SUMMARY

Various embodiments provide a double sided cooling chip package, wherein the package comprises a first heat sink; a second heat sink; a stacked chip arrangement comprising a first electronic chip, a second electronic chip and an interfacing substrate arranged between the first electronic chip and the second electronic chip and comprising electric circuitry on at least one main surface, wherein one of the first electronic chip and the second electronic chip is electrically connected to the electric circuitry of the interfacing substrate; and wherein the first electronic chip is attached to the first heat sink and the second electronic chip is attached to the second heat sink.

Furthermore, various embodiments provide a double sided cooling chip package, wherein the package comprises a first heat conductive substrate; a first electronic chip layer arranged on the first heat conductive substrate; an interfacing substrate comprising two opposite main surfaces having electrical conductive material arranged thereon, wherein one main surface is arranged on the first electronic chip layer; a second electronic chip arranged on the second main surface of the interfacing substrate; and a second heat conductive substrate arranged on the second electronic chip layer.

Moreover, various embodiments provide a method of manufacturing a double sided cooling chip package, wherein the method comprises attaching a first electronic chip on a first heat sink; electrically contacting an interfacing substrate having an electric circuitry to the first electronic chip so that the first electronic chip is in electrical connection to the electric circuitry; arranging a second electric chip on the interfacing substrate; and attaching the second electronic chip to a second heat sink.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIGS. 1A to 1F schematically illustrate views of a double sided cooling chip package according to an exemplary embodiment.

FIGS. 2A and 2B schematically shows a perspective view and a cross sectional view of a double sided cooling chip package according to an exemplary embodiment.

FIG. 3 shows a flowchart of a method of manufacturing a double sided cooling chip package according to an exemplary embodiment.

### DETAILED DESCRIPTION

In the following further exemplary embodiments of a double sided cooling chip package and a method of manufacturing the same will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a double sided cooling chip package comprising a stacked chip arrangement comprising at least two layers of electronic chips arranged on top of each other and sandwiching an interfacing substrate arranged in between and having at least one (heat and/or electrically) conductive surface. Furthermore, the stacked chip arrangement is sandwiched by two heat sinks one arranged on top of one of the electronic chip layer and the other one below the other of the electronic chip layers.

In particular, the first heat sink may be a bottom heat sink and the second heat sink may be a top heat sink, or vice versa. For example, the first heat sink may be thermally coupled to the first electronic chip and/or the second heat sink may be thermally coupled to the second electronic chip or vice versa. It should be noted that the electronic chips may form or may be part of a layer of the stacked chip arrangement. In particular, the package, or more particular the stacked chip arrangement, may of course comprise more than two layers, e.g. three, four, five, six or even more, including electronic chips. That is, the stacked chip arrangement may comprise three, four, five, six or even more electronic chips arranged on top of each other and/or in a staggered manner. It should be noted that in case of more than two layers of electronic chips it may be preferred that power chips or power dies may be arranged in the outermost electronic layers only (thus enabling an improved cooling via the outer heat sinks). In addition or alternatively each layer may comprise several electronic chips arranged side by side or laterally arranged in or on the layer. The first heat sink and/or the second heat sink may comprise or may consist of a lead frame, in particular a dual gauge lead frame.

By providing a stacked chip arrangement sandwiched between two heat sinks and having at least one heat and/or electrically conductive surface it may be possible to provide a chip package comprising a high density of electronic chips or dies while at the same time providing a good heat dissipation. Thus, the chip package may be in particular be useful for power dies or chips. In particular, the chip packages may have a high compactness and/or functionality and/or performance.

In the following exemplary embodiments of the double sided cooling chip package are described. However, the features and elements described with respect to these embodiments can be combined with exemplary embodiments of the method of manufacturing the double sided cooling chip package as well.

According to an exemplary embodiment of the double sided cooling chip package the interfacing substrate comprises a further electric circuitry on a further main surface opposite to the at least one main surface, wherein the further electric circuitry is electrically connected to the other one of the first electric chips and the second electric chip.

According to an exemplary embodiment of the double sided cooling chip package the interfacing substrate is selected out of the group consisting of: a direct copper bond substrate; a direct aluminum bond substrate; and a lead frame; a ball grid array; a stud bumping substrate; and a solder printing substrate.

In principle any kind of interfacing substrate may be used which comprises at least on one main surface, and preferably on both opposing main surfaces, electric circuitry which can be used for electrically contacting the first and/or second electronic chips or dies.

According to an exemplary embodiment the double sided cooling chip package further comprises an encapsulation at least partially encapsulating the first electronic chip, the interfacing substrate and the second electronic chip.

In particular, the encapsulation may comprise or may be formed by a molding compound or a molding material. The encapsulation may particular function as a passivation layer.

According to an exemplary embodiment the double sided cooling chip package further comprises at least one contact pad, wherein the electrical circuitry is electrically connected to the at least one contact pad.

In particular, the electrical circuitry may be connected to the at least one contact pad via bonding, e.g. a bonding wire, or adhered by an adhesive like solder. The contact pad may be used for electrically connecting the electrical circuitry and thus the electronic chip connected to the same with an output and/or input terminal and thus with the external environment.

According to an exemplary embodiment of the double sided cooling chip package at least one of the first electronic chip and the second electronic chip comprising a power chip.

In particular, the power chip may be a chip which is adapted to carry, conduct or switch electrical power signals or voltages which are higher than the signal level of common information signals. For example, the power chip may be adapted to carry or conduct signals having a voltage level of more than 20 V, in particular more than 50 V, even more particular of more than 100 V, or even more, while a power level may be above 25 W, in particular above 50 W, even more particular above 100 W or even higher. In particular, the power chip may be a power transistor, e.g. a MOSFET, SFET or IGBT, or the like.

According to an exemplary embodiment of the double sided cooling chip package the interface substrate is a direct copper bond substrate.

A direct copper bond (DCB) substrate may in particular a suitable interfacing substrate, since the outer copper layers of the DCB substrate may be suitable to provide electric conductivity or electrical conductor paths to the electronic chip(s) attached thereto. However, it should be noted that as well a direct aluminum bond (DAB) substrate may be used. In case of more than two layers or levels of electronic chips in the package, i.e. in case more than one interfacing substrate is used, the interfacing substrates may be arranged alternatively with respect to the layers of electronic chips.

According to an exemplary embodiment of the double sided cooling chip package the attaching of the first electronic chip or of the second electronic chip is performed via clip bonding.

In particular, the first electronic chip and the second electronic chip are attached to the first and second heat sink via clip bonding, respectively. Alternatively, the attaching may be performed via soldering or any other suitable attaching or adhesion method.

According to an exemplary embodiment the double sided cooling chip package further comprises at least one additional electronic chip layer comprising at least one electronic chip arranged between the first heat conductive substrate and the second heat conductive substrate and attached to an additional interfacing substrate.

In particular, a plurality of additional electronic chip layers may be provided, wherein each additional electronic chip layer is attached to a further additional interfacing substrate. Thus, a stacked chip arrangement comprising an alternating sequence of electronic chip layers and interfacing substrates may be provided. The stacked chip arrangement is then arranged between or sandwiched by the heat conductive substrates which forms the outer layers of such a multilayer arrangement. It should be noted that power chips, i.e. electronic chips adapted to withstand a relatively high voltage and/or current, e.g. above 50 V which is higher than the voltage levels of typical information signals in an electronic chip, for example, are preferably arranged as the outermost electronic chip layers only, i.e. the electronic chip layers arranged close to the heat conductive substrates, e.g. directly contacting the same.

In the following exemplary embodiments of the method of manufacturing a double sided cooling chip package are described. However, the features and elements described with respect to these embodiments can be combined with exemplary embodiments of the double sided cooling chip package as well.

In the following exemplary embodiments the method further comprises encapsulating the first electronic chip, the interfacing substrate and the second electronic chip at least partially with an encapsulation.

In the following exemplary embodiments of the method the attaching is performed by clip bonding.

In particular, at least one of the attaching of the first electronic chip to the first heat sink and the attaching of the second electronic chip to the second heat sink may be performed by clip bonding. Alternatively, an adhesion process like soldering may be used for the attaching.

In the following exemplary embodiments the method further comprises bonding the electric circuitry to a contact pad.

In particular, the contact pad may be separate to the first heat sink and/or to the first electronic chip and/or the second electronic chip. For example, the bonding may be performed by a wire bond or clip bond.

In the following exemplary embodiments of the method at least one of the attaching of the first electronic chip on the first heat sink and the attaching of second heat sink on the second electronic chip is performed by soldering.

In particular, both of the steps attaching the electronic chips to the heat sinks may be performed via soldering. Alternatively or additionally, clip bonding may be used as well.

In the following exemplary embodiments of the method at least one of the attaching of the second electronic chip to the interfacing substrate and the attaching of second interfacing substrate to the first electronic chip is performed by ball bonding.

That is, solder balls or a ball grid array, formed on the interfacing substrate and/or on the electronic chip(s) may be used when performing the respective attaching.

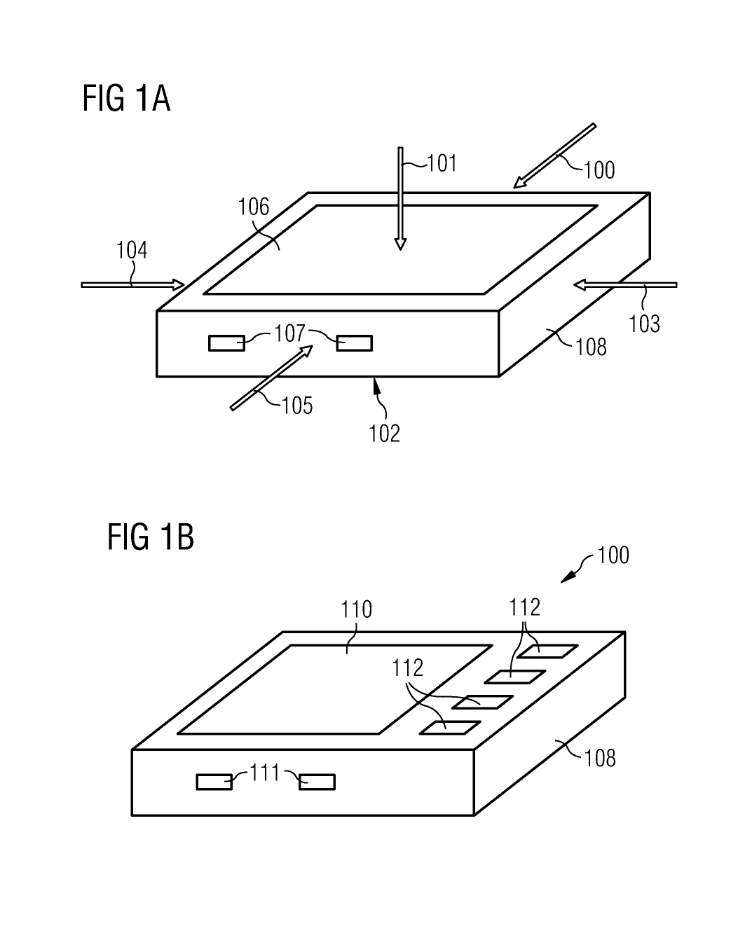

FIGS. 1A to 1F schematically illustrate views of a double sided cooling chip package according to an exemplary embodiment. In particular, FIG. 1A shows a schematic perspective top view of double sided cooling chip package 100, wherein an arrow 101 relates to a top view direction, arrow 102 relates to a bottom view direction, arrow 103 relates to a front view direction, arrow 104 relates to a back view direction, and arrow 105 relates to a side view direction shown in the following figures. In the perspective view of FIG. 1A of the double sided cooling chip package 100 a second or top heat sink 106 and two side contacts, e.g. electrical and/or thermal contacts, 107 can be seen which are free of an encapsulation material 108 and are thus exposed to an external environment.

In particular, FIG. 1B shows a schematic perspective bottom view of double sided cooling chip package 100. In the perspective view of FIG. 1B a first or bottom heat sink 110 and two other side contacts, e.g. electrical and/or thermal contacts 111 can be seen which are free of an encapsulation material 108 and are thus exposed to the external environment. In addition four contact pads 112 can be seen in FIG. 1B which are as well exposed to the external environment.

In particular, FIG. 1C shows a schematic bottom plan view of double sided cooling chip package 100 and showing the first heat sink 110, the four contact pads 112 and the encapsulation material 108, while FIG. 1D (a top plan view) shows the second heat sink 106 and the encapsulation material 108 as well.

In particular, FIG. 1E shows a schematic front/back plan view of double sided cooling chip package 100 and showing only the encapsulation material 108, while FIG. 1F (a side plan view) shows the encapsulation material 108 and the side contacts 107 as well.

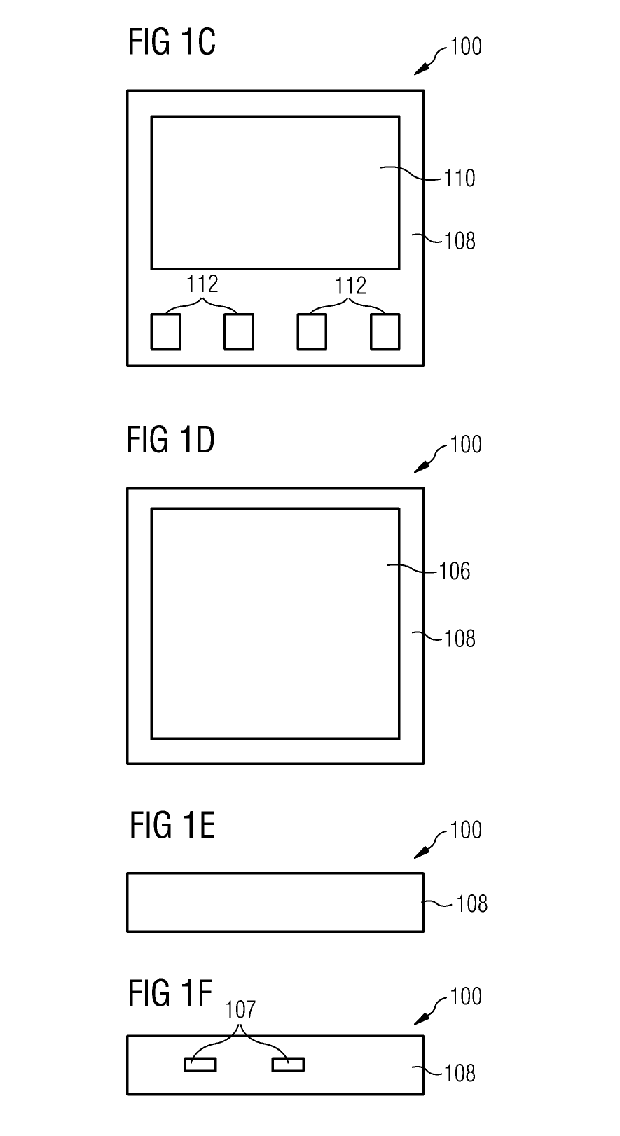

FIGS. 2A and 2B schematically shows a perspective view and a cross sectional view, respectively of a double sided cooling chip package 100 according to an exemplary embodiment. In particular, FIG. 2A shows a perspective bottom view of the double sided cooling chip package 100 corresponding to FIG. 1B having additionally included a cross sectional line along which a cross section of the double sided cooling chip package 100 shown in FIG. 2B is taken.

In particular, FIG. 2B shows the first heat sink or heat conductive substrate 110 formed by a heat conductive material like a metal, e.g. copper, aluminum or the like. The first heat sink may comprise or may be formed by a lead frame, e.g. a dual gauge lead frame. A first electronic chip 210 is attached to the first heat sink 110, e.g. by clip bonding or by a soldering layer 211. Furthermore, an interfacing substrate 212 may be attached, e.g. soldered to the first electronic chip 210. Preferably, the interfacing substrate 212 comprises electrically conductive material on both main surfaces. The electrically conductive material may be used to form electrically conductive paths or electric circuitry. For example, the interfacing substrate 212 may be a direct copper bond (DCB) substrate comprising a core material layer 215 and two external layers 216 and 217 comprising or consisting of copper. The core material layer may comprise or may consist of an electrically non-conductive or dielectric material, e.g. ceramics or a polyimide (Kapton) material. Alternatively to a DCB substrate a direct aluminum bond substrate or any other suitable substrate providing electrical conductivity at the main surfaces may be used.

The soldering may be performed by a solder layer 218 or a solder ball 219. However, any suitable attaching method may be used which is suitable to provide an electrical contact between the electrically conductive layer 216 of the interfacing substrate 212 and the first electronic chip 210.

A second electronic 220 is attached to the other electrically conductive layer 217 of the interfacing substrate 212. In the example of FIG. 2B the attaching is performed by soldering using solder balls or ball bonds 221. In addition, the other electrically conductive layer 217 of the interfacing substrate 212 is electrically connected to the contact pads 112 via a wire bond 222, while the electrically conductive layer 216 may be soldered directly to the contact pads 112.

The second electronic chip 220 in turn is attached to the second heat sink 106, which is schematically shown in FIG. 2B by a solder layer 223. Furthermore, the embodiment of FIG. 2B shows an optional via 224 connecting the first heat sink 110 and the second heat sink 106. The via 224 is filled by an electrically and/or thermally conductive material like copper, aluminum or the like.

For forming the dual side cooling chip package 100 the encapsulation material 108 is formed or molded about the electric and/or electronic components, wherein the encapsulation material still exposes the first and second heat sinks and the contact pads.

It should be noted that the side contacts shown in FIG. 2A may be part of the interfacing substrate 212, for example, bit cannot be seen in FIG. 2B due to the chosen cross section.

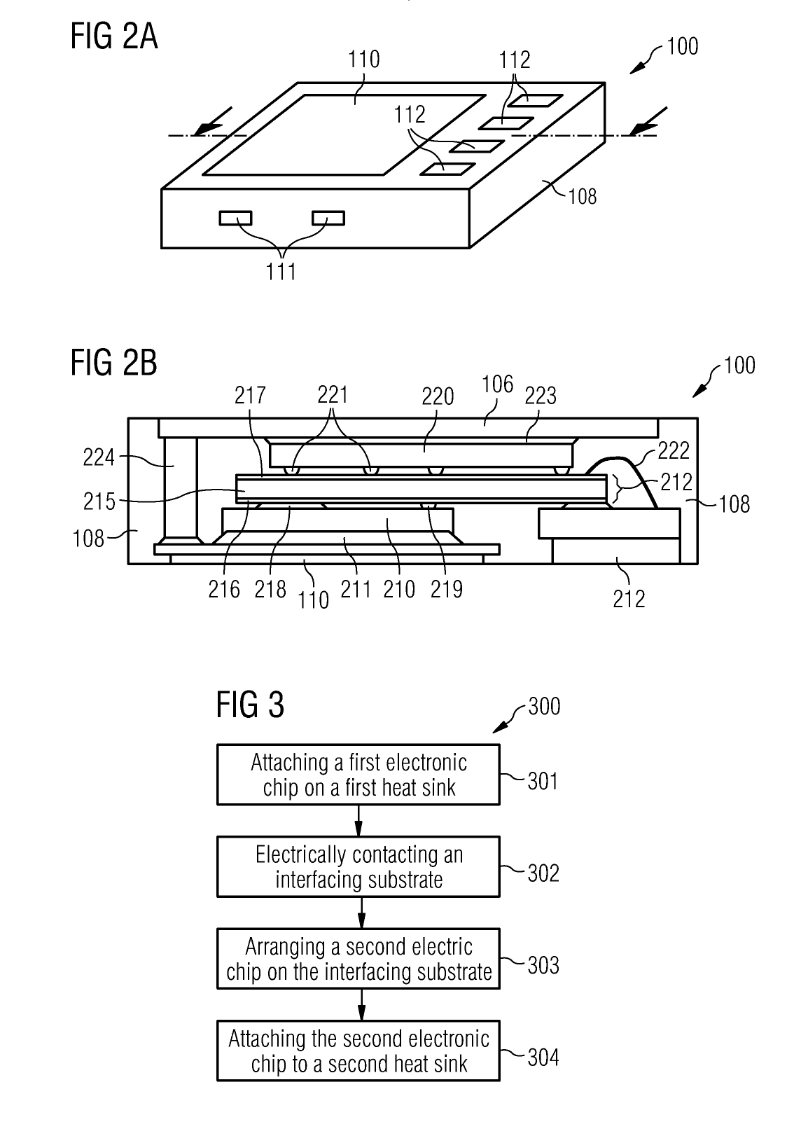

FIG. 3 shows a flowchart of a method of manufacturing a double sided cooling chip package according to an exemplary embodiment. In particular, the method 300 comprising attaching a first electronic chip on a first heat sink (step 301) and electrically contacting an interfacing substrate (step 302) comprising an electric circuitry to the first electronic chip so that the first electronic chip is in electrical connection to the electric circuitry. In addition the method comprises arranging a second electric chip on the interfacing substrate (step 303); and attaching the second electronic chip to a second heat sink (step 304). In addition, optionally an encapsulation may be formed by a molding or another suitable material. Before the optional forming of the encapsulation the interfacing substrate may be electrically connected to contact pads by via bonding, for example.

Summarizing exemplary embodiments may provide a double sided cooling chip package wherein a design idea may be the using of DCB substrate (with electrical routing on top of both top and bottom surfaces) and electronic chips or stacked dies which are bond on the surfaces of the DCB. In addition to a front heat sink (e.g. attached by clip bonding to the front side of one electronic chop) an additional back heat sink may be bond onto the backside of another chip to enlarge the double sided heat sink area for maximize double sided cooling. Thus, stacked chips or stacked dies may be arranged inside a double sided cooling (DSC) chip package by using a DCB substrate.

In particular, when using a DSC chip package according to an exemplary embodiment it may be possible to maintain the same package layout and/or size on PCB but with stacked dies inside the package by using DCB substrate as an interfacing substrate. A front heat sink may be attached on a top chip, wherein the surface of the heat sink may be much bigger than chip size possibly enhancing heat dissipation capability. Furthermore, while maintaining the same package layout it may be possible to enable further product expansion by having stacked dies. The provision of such stacked dies may increase compactness and functionality and/or performance of the package. In particular, the package according to the exemplary embodiment may enable double sided cooling and heat dissipation capability with stacked dies.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A double sided cooling chip package, comprising:
a first heat sink;
a second heat sink; and
a stacked chip arrangement comprising a first electronic chip, a second electronic chip and an interfacing substrate arranged between the first electronic chip and the second electronic chip and comprising electric circuitry on at least one main surface,
wherein one of the first electronic chip and the second electronic chip is electrically connected to the electric circuitry of the interfacing substrate; and
wherein the first electronic chip is attached to the first heat sink and the second electronic chip is attached to the second heat sink.

2. The double sided cooling chip package according to claim 1,
wherein the interfacing substrate comprises a further electric circuitry on a further main surface opposite to the at least one main surface; and
wherein the further electric circuitry is electrically connected to the other one of the first electric chips and the second electric chip.

3. The double sided cooling chip package according to claim 1,
wherein the interfacing substrate is selected out of the group consisting of:
a direct copper bond substrate;
a direct aluminum bond substrate;
a lead frame;
a ball grid array;
a stud bumping substrate; and
a solder printing substrate.

4. The double sided cooling chip package according to claim 1, further comprising an encapsulation at least partially encapsulating the first electronic chip, the interfacing substrate and the second electronic chip.

5. The double sided cooling chip package according to claim 1, further comprising at least one contact pad, wherein the electrical circuitry is electrically connected to the at least one contact pad.

6. The double sided cooling chip package according to claim 1, wherein at least one of the first electronic chip and the second electronic chip comprising a power chip.

7. The double sided cooling chip package according to claim 1, wherein the interface substrate is a direct copper bond substrate.

8. The double sided cooling chip package according to claim 1, wherein the attaching of the first electronic chip or of the second electronic chip is performed via clip bonding.

9. A double sided cooling chip package, comprising:
a first heat conductive substrate;
a first electronic chip layer arranged on the first heat conductive substrate;
an interfacing substrate comprising two opposite main surfaces having electrical conductive material arranged thereon, wherein one main surface is arranged on the first electronic chip layer;
a second electronic chip layer arranged on the second main surface of the interfacing substrate; and
a second heat conductive substrate arranged on the second electronic chip layer.

10. The double sided cooling chip package according to claim 9, further comprising:
at least one additional electronic chip layer comprising at least one electronic chip arranged between the first heat conductive substrate and the second heat conductive substrate and attached to an additional interfacing substrate.

11. Method of manufacturing a double sided cooling chip package, the method comprising:
attaching a first electronic chip on a first heat sink;
electrically contacting an interfacing substrate comprising an electric circuitry to the first electronic chip so that the first electronic chip is in electrical connection to the electric circuitry;
arranging a second electric chip on the interfacing substrate; and
attaching the second electronic chip to a second heat sink.

12. Method according to claim 11, further comprising:
encapsulating the first electronic chip, the interfacing substrate and the second electronic chip at least partially with an encapsulation.

13. Method according to claim 11, wherein the attaching is performed by clip bonding.

14. The method according to claim 11, further comprising:
bonding the electric circuitry to a contact pad.

15. The method according to claim 11, wherein at least one of the attaching of the first electronic chip on the first heat sink and the attaching of second heat sink on the second electronic chip is performed by soldering.

16. The method according to claim 11, wherein at least one of the attaching of the second electronic chip to the interfacing substrate and the attaching of second interfacing substrate to the first electronic chip is performed by ball bonding.
